(19) United States
(12) Patent Application Publication
(10) Pub. No.: US 2014/0159815 A1
(43) Pub. Date: Jun. 12, 2014

(54) High Bandwidth High Sensitivity CMOS Trans-Impedance Amplifier

(71) Applicant: SiFotonics Technologies Co., Ltd., Woburn, MA (US)

(72) Inventors: Shuicheng Cai, Shanghai (CN); Yuqian Wu, Winchester, MA (US); Chunmei Li, Shanghai (CN)

(73) Assignee: SiFotonics Technologies Co., Ltd., Woburn, MA (US)

(21) Appl. No.: 14/101,167

(22) Filed: Dec. 9, 2013

Related U.S. Application Data
(60) Provisional application No. 61/797,513, filed on Dec. 10, 2012.

(51) Int. Cl. H03F 3/45

(52) U.S. Cl. CPC H03F 3/45071
USPC 330/260

(57) ABSTRACT

A CMOS trans-impedance amplifier (TIA) in accordance with the present disclosure can achieve improved bandwidth and sensitivity by utilizing novel shunt-shunt feedback and inductor peaking. The proposed design simultaneously improves 10-Gbps TIA performance in terms of bandwidth and sensitivity, while the TIA may be fabricated through a standard 0.13 μm CMOS process. Performance of the TIA in accordance with the present disclosure is much better than that of conventional CMOS TIA in the 10-Gbps CMOS TIA design and applications.

### CROSS-REFERENCE TO RELATED PATENT APPLICATION

This application is the non-provisional application of, and claims the priority benefit of U.S. Patent Application Nos. 61/797,513, filed on Dec. 10, 2012, which is herein incorporated by reference in its entirety.

### BACKGROUND

1. Technical Field

The present disclosure is related to fiber optics communication and, more particularly, to a novel complementary metal-oxide-semiconductor (CMOS) trans-impedance amplifier (TIA) for fiber optics communication.

2. Description of Related Art

One main advantage of fiber optics communication is large bandwidth, allowing the transfer of data quickly. Accordingly, modern communication networks and servers, which need to transfer great amount of data in high speed, must adopt the fiber optics communication technology. When more and more consumer electronics are “online” or connected to the Internet to receive and transmit data under high speed, the application of the fiber optics communication technology becomes an even more irresistible trend.

The TIA is an important chip on the optical communication receiver side, whose performance is seriously dependent on process. The TIA must provide sufficient bandwidth to meet the bandwidth requirements, while the TIA itself must be a low noise device with high sensitivity in order to recover weak optical signals from long-distance transmission to normal signals. Compared to CMOS devices, III/V and SiGe devices have the advantages in bandwidth and noise performance, but their costs are much higher than those of CMOS devices. Usually, for applications of low data rate below 10 gigabits-per-second (Gbps), designers use CMOS to lower the product cost while achieving acceptable performance. However, for applications of data rates of 10 Gbps and higher, it becomes necessary to adopt III/V or SiGe devices to achieve the required performance.

### SUMMARY

The present disclosure provides a technique of using shunt-shunt feedback and inductor peaking technology to improve the bandwidth and sensitivity of the TIA. The new 10-Gbps TIA, which is fabricated through a standard 0.13 μm CMOS process, can meet the bandwidth and sensitivity requirements for 10-Gbps applications. To the best of the inventors' knowledge, this is the first 10-Gbps CMOS TIA fabricated with the standard 0.13 μm process that can achieve a level of performance comparable to III/V and SiGe commercial TIAs. Moreover, the new technology in accordance with the present disclosure can also be applied in the next generation CMOS process for designing 40-Gbps and 100-Gbps TIAs.

In one aspect, a TIA in accordance with the present disclosure may include a TIA core, a single-end-to-differential converter coupled to the TIA core, a limiting amplifier coupled to the single-end-to-differential converter and an output buffer coupled to the limiting amplifier. The TIA core may include a voltage amplifier, an output inductor and a feedback resistor. The output inductor may be coupled between an output terminal of the voltage amplifier and an input terminal of the single-end-to-differential converter. The feedback resistor may be coupled between an input terminal of the voltage amplifier and the input terminal of the single-end-to-differential converter.

In one embodiment, the TIA may include circuitry having features with MOS device lengths as small as 0.13 μm approximately.

In one embodiment, the TIA may include a CMOS circuit having features with MOS device lengths as small as 65 nm approximately.

In one embodiment, the TIA may include a CMOS circuit having features with MOS device lengths as small as 40 nm approximately.

In one embodiment, the TIA may be configured to meet bandwidth and sensitivity requirements for 10 Gbps applications.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain the principles of the present disclosure. The drawings may not necessarily be in scale so as to better present certain features of the illustrated subject matter.

FIG. 1 is a functional block diagram of a conventional CMOS TIA.

FIG. 2 is a functional block diagram of a high-speed CMOS TIA in accordance with an embodiment of the present disclosure.

FIG. 3 is a functional block diagram of another conventional CMOS TIA.

FIG. 4 is a chart of TIA bandwidth versus inductor value in accordance with an embodiment of the present disclosure.

### DETAILED DESCRIPTION OF THE PREFERRED EMBODIMENTS

### Overview

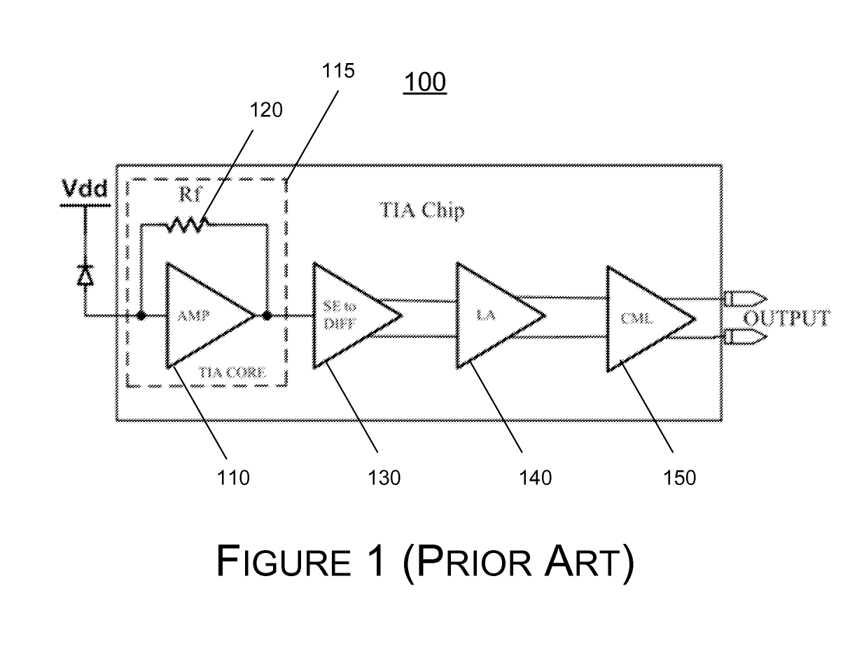

FIG. 1 illustrates a functional block diagram of a conventional CMOS TIA 100. As shown in FIG. 1, the CMOS TIA 100 includes a voltage amplifier (AMP) 110, a feedback resistor (Rf) 120, a single-end-to-differential mode converter 130, a limiting amplifier (LA) 140, and an output buffer (CML) 150. The TIA core 115 of the CMOS TIA 100 is indicated by the portion contained in the dotted line, and includes the voltage amplifier 110 and the feedback resistor 120. The TIA core 115 is critical to the operation of the CMOS TIA 100, as it determines the overall performance of the CMOS TIA 100 in terms of bandwidth and sensitivity.

The transfer function of the TIA core 115 can be expressed by Equation (1) as follows:

$${Z}_{T} = - \frac{{A}_{0} \frac{{ω}_{0}}{{C}_{tot}}}{{A}_{0} \frac{{ω}_{0}}{{C}_{tot} {R}_{f}} + ( {ω}_{0} + \frac{1}{{C}_{tot} {R}_{f}} ) s + {s}^{2}} \qquad ( 1 )$$

Where A₀ is the gain of the voltage amplifier 110, ω₀ is the main pole of voltage amplifier 110, and Cₜₒₜ is the total capacitance of an input node to the CMOS TIA 100, when A₀>>1,

$${ω}_{0} >> \frac{{A}_{0}}{{C}_{tot} {R}_{f}} .$$

In addition, the bandwidth of the TIA core 115 can be expressed by Equation (2) as follows:

$$BW \approx \frac{{A}_{0}}{2 π \cdot {C}_{tot} {R}_{f}} . \qquad ( 2 )$$

For specific process, the gain bandwidth product of a device is a constant. Generally, a III/V or SiGe device tends to have much greater gain bandwidth product than that of a CMOS device. In Equation (2), the bandwidth of a TIA is denoted as BW, and the gain is denoted as R_{f}. When BW is required to be high to achieve 10-Gbps data rate, R_{f} needs to be reduced in order to meet the bandwidth requirement. However, the reduction in gain R_{f} will inevitably lead to increased equivalent TIA input referred noise, thereby reducing the sensitivity of the TIA.

In the CMOS TIA 100 shown in FIG. 1, metal-oxide-semiconductor (MOS) devices are used to implement the voltage amplifier 110. Given that a MOS transistor trans-conductance is smaller and its parasitic capacitance is larger compared to a III/V or SiGe devices, the CMOS TIA 100 is forced to reduce the gain to meet the bandwidth requirements in 10-Gbps applications in order to achieve the high bandwidth. Moreover, noise performance of the CMOS TIA 100 is much worse than a III/V or SiGe process TIA, and it is difficult for the CMOS TIA 100 to reach commercial requirements for sensitivity.

In order to design a CMOS TIA that can achieve adequate bandwidth and high sensitivity simultaneously, a new shunt-shunt feedback and inductor peaking technology is proposed in the present disclosure to achieve this goal.

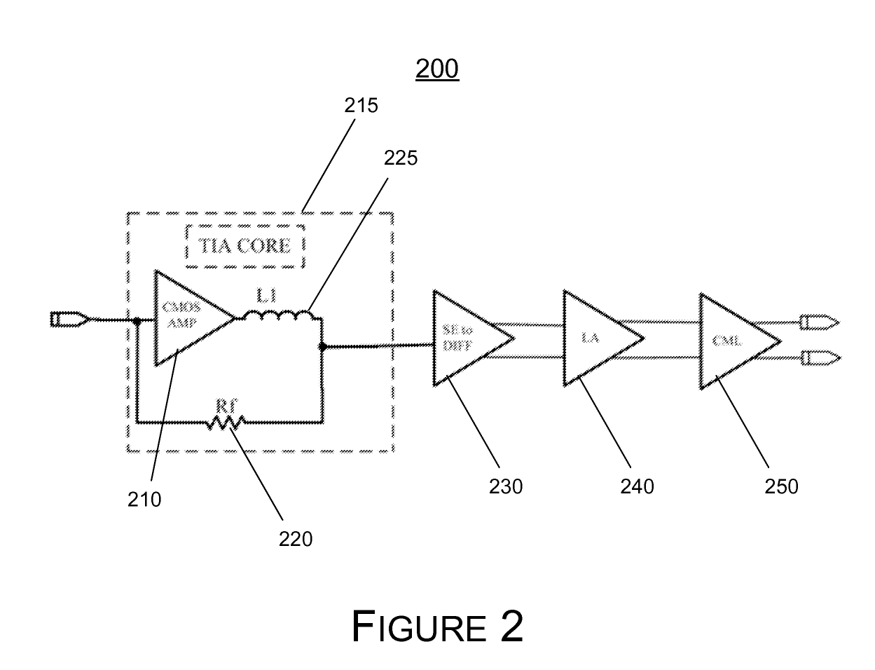

FIG. 2 illustrates a functional block diagram of a high-speed CMOS TIA 200 in accordance with an embodiment of the present disclosure. As shown in FIG. 2, the CMOS TIA 200 includes a voltage amplifier (AMP) 210, a feedback resistor (Rf) 220, an output inductor (L1) 225, a single-end-to-differential mode converter 230, a limiting amplifier (LA) 240, and an output buffer (CML) 250. The TIA core 215 of the CMOS TIA 200 is indicated by the portion contained in the dotted line, and includes the voltage amplifier 210, the output inductor 225 and the feedback resistor 220. The output of the voltage amplifier 210 is connected or otherwise coupled to the output inductor 225. The output inductor 225 is coupled to the feedback resistor 220. The feedback resistor 220 is coupled to the input of the CMOS TIA 200. A node between the output inductor 225 and the feedback resistor 220 is coupled to an input terminal of the single-end-to-differential mode converter 230. The output inductor 225 works as part of the feedback loop, playing an important role of improving the bandwidth and gain of the voltage amplifier 210, while reducing output noise.

In one embodiment, the CMOS TIA 200 may be fabricated by a standard 0.13 μm CMOS process, and can meet the bandwidth and sensitivity requirements for 10-Gbps applications. In one embodiment, the CMOS TIA 200 may include circuitry having features with MOS device lengths as small as 0.13 micron (μm) approximately. In another embodiment, the CMOS TIA 200 may include a CMOS circuit having features with MOS device lengths as small as 65 nanometers (nm) approximately. In still another embodiment, the CMOS TIA 200 may include a CMOS circuit having features with MOS device lengths as small as 40 nm approximately.

The transfer function of the TIA core 215 can be expressed by Equation (3) as follows:

$${Z}_{T} = \frac{{A}_{V} {R}_{f} + sL 1}{1 - {A}_{V} + {sC}_{tot} ( {R}_{f} + sL 1 )} . \qquad ( 3 )$$

The −3 dB bandwidth of the TIA core 215 can be expressed by Equation (4) as follows:

$$BW = \vert \frac{\begin{matrix}j \sqrt{2} \frac{{A}_{V} - 1}{{A}_{V}} {L}_{1} + j {R}_{f}^{2} {C}_{tot} - \\ \sqrt{\begin{matrix}{C}_{tot} {R}_{f}^{2} ( 4 {L}_{1} ( {A}_{V} ( \sqrt{2} - 1 ) + 1 ) - {R}_{f}^{2} {C}_{tot} ) - \\ 2 {{L}_{1}^{2} ( \frac{{A}_{V} - 1}{{A}_{V}} )}^{2} - 2 \sqrt{2} {L}_{1} {R}_{f}^{2} {C}_{tot} ( \frac{3 {A}_{V} - 1}{{A}_{V}} )\end{matrix}}\end{matrix}}{4 {R}_{f} {C}_{tot} {L}_{1} π} \vert , \qquad ( 4 )$$

where A_{V} is the gain of the voltage amplifier 210.

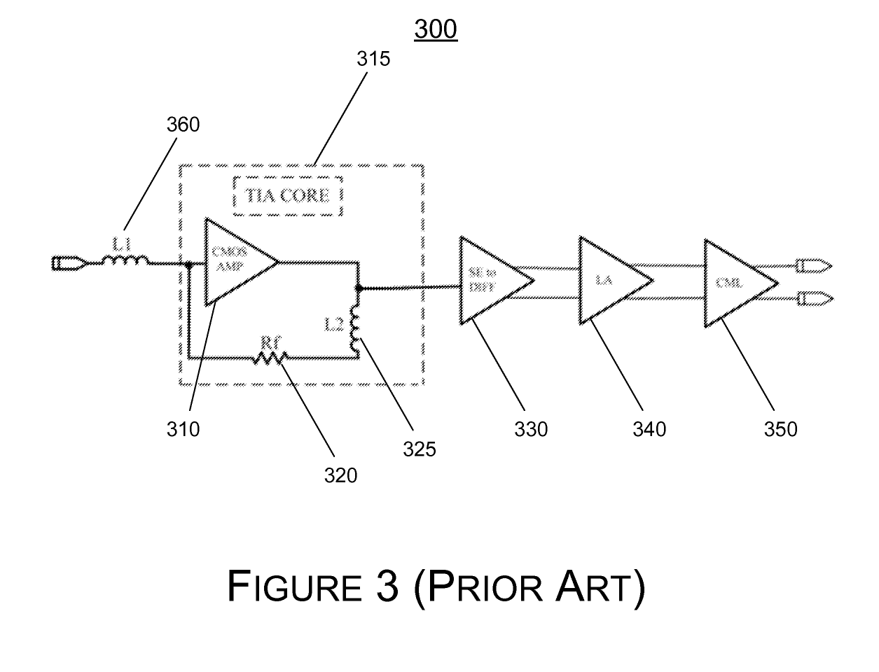

FIG. 3 illustrates a functional block diagram of another conventional CMOS TIA 300 that is structured differently from the conventional CMOS TIA 100 of FIG. 1. As shown in FIG. 3, the CMOS TIA 300 includes a voltage amplifier (AMP) 310, a feedback resistor (Rf) 320, a first inductor (L1) 360, a second inductor (L2) 325, a single-end-to-differential mode converter 330, a limiting amplifier (LA) 340, and an output buffer (CML) 350. The TIA core 315 of the CMOS TIA 300 is indicated by the portion contained in the dotted line, and includes the voltage amplifier 310, the second inductor 325 and the feedback resistor 320.

The major difference between the conventional CMOS TIA 300 and the CMOS TIA 200 of the present disclosure is that, in the conventional CMOS TIA 300, the output of the voltage amplifier 310 is connected or otherwise coupled directly to the second stage (i.e., the single-end-to-differential mode converter 330), and as a result the voltage amplifier 310 sees a greater capacitive loading which is the sum of the output of the voltage amplifier 310 and the input of second stage. In contrast, in the proposed topology shown in FIG. 2, the node between the feedback resistor 220 and the output inductor 225 is connected or otherwise coupled to the input of the second stage. Advantageously, in the CMOS TIA 200 according to the present disclosure, the pole of the voltage amplifier 210 is pushed to high because the output of the voltage amplifier 210 sees a smaller parasitic capacitive loading than does the voltage amplifier 310 of the conventional CMOS TIA 300.

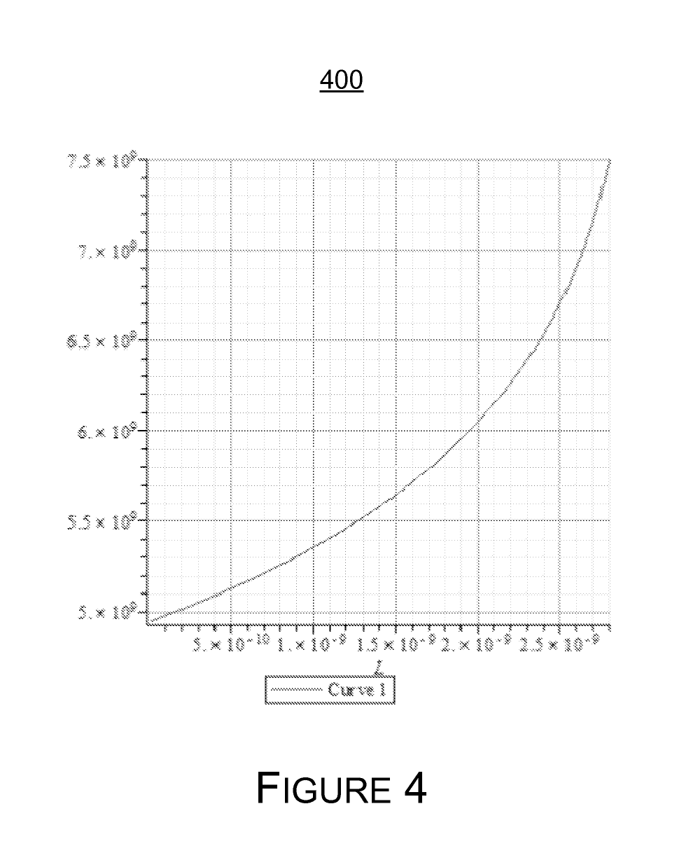

FIG. 4 shows a chart 400 of TIA bandwidth versus inductor value in accordance with an embodiment of the present disclosure. As shown in FIG. 4, in a simulation the inductor L1 can significantly increase the TIA bandwidth. Therefore, compared to conventional TIAs, a feedback resistor Rf with a resistance of higher value can be used in the new TIA core (e.g., TIA core 215 and TIA core 315) while keeping the same TIA bandwidth. Higher resistance value for the feedback resistor Rf results in better sensitivity.

### Additional Note

Although some embodiments are disclosed above, they are not intended to limit the scope of the present disclosure. It will be apparent to those skilled in the art that various modifications and variations can be made to the disclosed embodiments of the present disclosure without departing from the scope or spirit of the present disclosure. In view of the foregoing, the scope of the present disclosure shall be defined by the following claims and their equivalents.

What is claimed is:

1. A trans-impedance amplifier (TIA), comprising:
a TIA core comprising:
a voltage amplifier;
an output inductor; and
a feedback resistor;
a single-end-to-differential converter coupled to the TIA core;
a limiting amplifier coupled to the single-end-to-differential converter; and
an output buffer coupled to the limiting amplifier,
wherein:
the output inductor is coupled between an output terminal of the voltage amplifier and an input terminal of the single-end-to-differential converter,
the feedback resistor is coupled between an input terminal of the voltage amplifier and the input terminal of the single-end-to-differential converter.

2. The TIA of claim 1, wherein the TIA comprises circuitry having features with MOS device lengths as small as 0.13 micron (μm) approximately.

3. The TIA of claim 1, wherein the TIA comprises a complementary metal-oxide-semiconductor (CMOS) circuit having features with MOS device lengths as small as 65 nanometers (nm) approximately.

4. The TIA of claim 1, wherein the TIA comprises a complementary metal-oxide-semiconductor (CMOS) circuit having features with MOS device lengths as small as 40 nanometers (nm) approximately.

5. The TIA of claim 1, wherein the TIA is configured to meet bandwidth and sensitivity requirements for 10 gigabits-per-second (Gbps) applications.
